(19) United States
(12) Patent Application Publication
(10) Pub. No.: US 2005/0275412 A1
(43) Pub. Date: Dec. 15, 2005

(54) Cable power indicator

(76) Inventors: Bill Kwong, Saratoga, CA (US); Victor Chuan-Chen Wu, Cupertino, CA (US)

Correspondence Address: BRUCE H. TROXELL, 5205 LEESBURG PIKE, SUITE 1404, FALLS CHURCH, VA, 22041, US

(21) Appl. No.: 10/863,209

(22) Filed: Jun. 9, 2004

(51) Int. Cl. H04B 3/46; G01R 31/02; G01R 27/04; G01R 27/32

(52) U.S. Cl. 324/542

(57) ABSTRACT

A cable power indicator for indicating the power of a power cable is presented or not, which comprises: a power cable, having at least one connector and a cable, wherein, the cable comprises at least one positive wire and a ground wire, and the positive wire and ground wire is connected to the connector respectively; an indicator, coupled to the positive wire and the ground wire of the connector at the end of the power cable, for indicating the power of the power cable being presented or not; and a resistor, coupled to the indicator for limiting the current draw to the indicator; thereby, the presence of power at the end of the power cable can be easily confirmed by the indicator.

### BACKGROUND OF THE INVENTION

1. Field of Invention

The present invention relates to the addition of a simple low cost LED to the end of a power cable that connects to the power input of any electronic device to provide positive indication that power is present to the device. The power indicator is useful in determining if power is present right at the input of a device or electronic modules that does not have any power indicator light, such as hard drives, and where the power cable runs a long distance from the power source to the device.

2. Description of Related Art

In many applications, an electronic module or device that does not have build in power indicator is connected to a power supply via a connecting power cable. When such device does not function, it is difficult to determine if the malfunction is due to the defective device, defective power cable or problem with the power source. This is particularly more difficult if the device is connected to the power source that is not easily accessible. Having a simple power indicator light at the end of the connecting cable can easily identify whether the cause of the problem is due to a defective device, a defective connecting power cable, or problem from the power source.

### SUMMARY OF THE INVENTION

The object of the present invention is the addition of a low cost LED at the end of a power cable to indicate the presence of power at the connecting point between the power cable and the attached device. To limit the current draw of the LED to 10 mA when connected to a 5 volt power source, a 100 ohms low power resistor is added in series. In this invention, a commercially available LED with an integrated 100 ohms resistor is selected for this application. This invention can apply to any voltage from the power source, the value of the current limiting resistor can be adjusted to ensure the current draw to the LED is 10 mA by applying the simple OHM's law: Voltage=Current×Resistance. The LED with the resistor in series is connected between the positive wire and the ground wire of the connector at the end of the power cable. When the power cable is attached to the power source, the LED light will stay lit at the connector end that attaches to the electronic device. If the power cable is defective or there is no power from the power source, the LED will be off.

### BRIEF DESCRIPTION OF THE DRAWINGS

The present invention can be more fully understood by reference of the following description and accompanying drawings, in which:

FIG. 1 shows the schematic of the LED together with the current limiting resistor at the end of a power cable; and

FIG. 2 illustrates how a LED light is integrated into the rubber housing of a connector in a Serial ATA hard drive power cable.

### DETAILED DESCRIPTION OF THE PREFERRED EMBODIMENTS

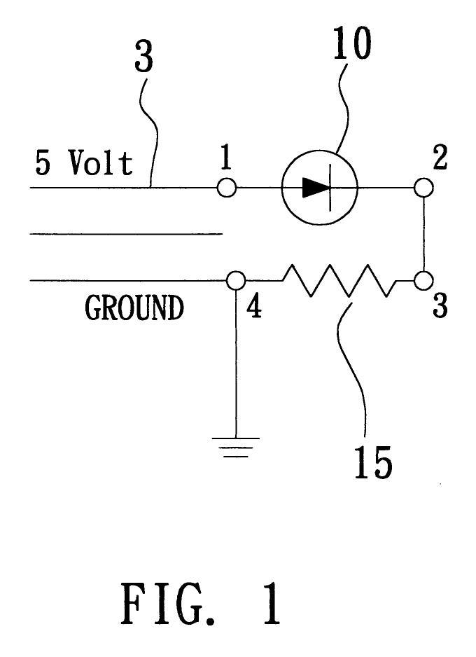

Referring to FIG. 1, which shows how an indicator 10 is connected to the 5 volt and to the current limiting resistor 15, which in turn connects to the ground line of the power cable 3. As shown in the FIG. 1, the indicator 10 of the cable 3 is connected to the power source, such as but not limited to a 5 volt power supply, for indicating the power of the cable 3 is presented or not. And for preventing the indicator 10 from burning, a current limiting resistor 15 is added in series to the indicator 10, and the value of the current limiting resistor 15 is around 10 mA according to the application. In this embodiment of the present invention, a commercially available LED 10 with an integrated 100 ohms resistor 15 is selected for this application. But a lamp or a buzzer also can be used to replace the LED for indicating. This invention can apply to any voltage from the power source, the value of the current limiting resistor 15 can be adjusted to ensure the current draw to the LED 10 is 10 mA by applying the simple OHM's law: Voltage=Current×Resistance.

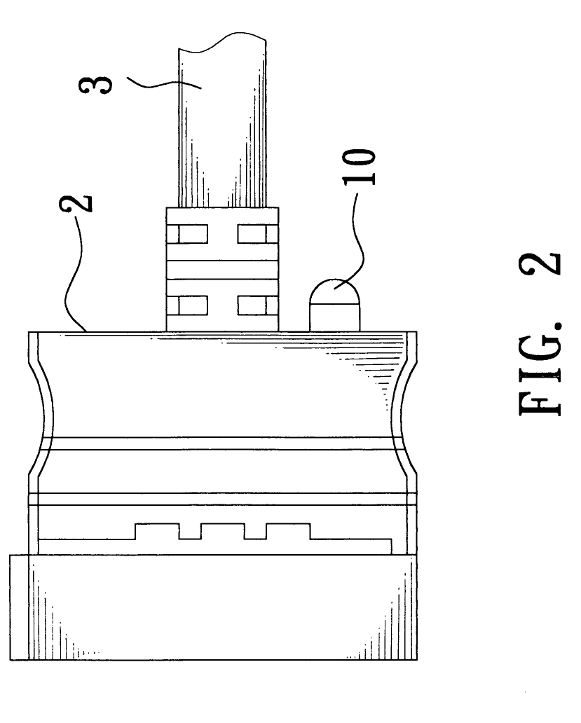

Referring to FIG. 2, which illustrates an example of a power cable 3 with the LED 10 integrated inside the connector 2 moulds using the wiring schematic in FIG. 1. LED 10 is shown with its bulb extruded outside the connector mould 2, which encapsulates all the electrical circuits of the LED 10, the current limiting resistor 15 and all the wirings are inside the power cable 3. The LED 10 with the resistor 15 in series is connected between the positive wire and the ground wire of the connector 2 at the end of the power cable 3. When the power cable is attached to the power source, the LED 10 light will stay lit at the connector end that attaches to the electronic device. If the power cable 3 is defective or there is no power from the power source, the LED 10 will be off.

While the invention has been disclosed with reference to preferred embodiments thereof, it is to be understood that modifications or variations may be easily made without departing from the spirit of this invention, which is defined in the appended claims.

1. A cable power indicator for indicating the power of a power cable is presented or not, which comprises:
a power cable, having at least one connector and a cable, wherein, said cable comprises at least one positive wire and a ground wire, and said positive wire and said ground wire is connected to said connector respectively;
an indicator, coupled to said positive wire and said ground wire of said connector at the end of said power cable, for indicating the power of said power cable being presented or not; and
a resistor, coupled to said indicator for limiting the current draw to said indicator;
thereby, the presence of power at the end of said power cable can be easily confirmed by the indicator.

2. The cable power indicator according to claim 1, wherein said indicator preferably is a LED.

3. The cable power indicator according to claim 1, wherein said indicator preferably is a lamp.

4. The cable power indicator according to claim 1, wherein said indicator preferably is a buzzer.

5. The cable power indicator according to claim 1, wherein said resistor connected to said indicator is in series.

6. The cable power indicator according to claim 1, wherein said resistor preferably is a low power resistor.

7. The cable power indicator according to claim 1, wherein said power cable preferably is a Serial ATA power cable.
